(19) United States
(12) Patent Application Publication
(10) Pub. No.: US 2003/0235998 A1
(43) Pub. Date: Dec. 25, 2003

(54) Method for eliminating standing waves in a photoresist profile

(76) Inventor: Ming-Chung Liang, Taipei (TW)

Correspondence Address: Finnegan, Henderson, Farabow,, Garrett & Dunner, L.L.P., 1300 I Street, N.W., Washington, DC, 20005-3315, US

(21) Appl. No.: 10/177,145

(22) Filed: Jun. 24, 2002

(51) Int. Cl. H01L 21/31

(52) U.S. Cl. 438/758

(57) ABSTRACT

A semiconductor manufacturing method that includes defining a substrate, depositing a layer of first material over the substrate, providing a layer of photoresist over the layer of first material, patterning and defining the photoresist layer to form at least one photoresist structure having at least one substantially vertical sidewall and one substantially horizontal surface, wherein a surface of the at least one substantially vertical sidewall is in the shape of a standing wave, and depositing a layer of polymer over the patterned and defined photoresist layer, wherein the polymer layer is substantially conformal and covers the at least one substantially vertical sidewall and one substantially horizontal surface, and wherein the polymer layer covers the standing wave on the surface of the at least one substantially vertical sidewall to form a substantially smooth profile.

### DESCRIPTION OF THE INVENTION

1. Field of the Invention

This invention relates in general to a semiconductor manufacturing process and, more particularly, to a novel manufacturing process to improve conventional photolithographic methods.

2. Background of the Invention

With sub-micron semiconductor manufacturing process being the prevalent technology, the demand for a high-resolution photolithographic process has increased. The resolution of a conventional photolithographic method is primarily dependent upon the wavelength of a light source, which dictates that there be a certain fixed distance between patterns on a photoresist. In addition, conventional photolithographic methods often leave a rough profile on vertical surfaces of an etched photoresist due to the characteristics of conventional etching processes. A photoresist having a rough profile often presents itself in the shape of a “standing wave” on the photoresist surfaces. The lack of uniformity on the photoresist surfaces may additionally hinder reduction in the critical dimensions of the semiconductor manufacturing process, and presents an additional obstacle to accurate definition of desired patterns during subsequent manufacturing steps, resulting in decreased process yield.

It is accordingly a primary object of the invention to provide a method to eliminate the standing waves on an etched photoresist surface.

### SUMMARY OF THE INVENTION

In accordance with the invention, there is provided a semiconductor manufacturing method that includes defining a semiconductor substrate, depositing a layer of first material over the semiconductor substrate, providing a layer of photoresist over the layer of first material, patterning and defining the photoresist layer to form at least one substantially vertical sidewall having a surface and one substantially horizontal sidewall, and depositing a layer of polymer over the patterned and defined photoresist layer, wherein the polymer layer is substantially conformal and covers the at least one substantially vertical sidewall of the photoresist layer to form a substantially smooth profile.

In one aspect, the layer of polymer is deposited with plasma enhanced chemical vapor deposition at a pressure of between approximately 7 mTorr and 30 mTorr.

In another aspect, the layer of first material comprises one of polysilicon, dielectric material or metallic material.

Also in accordance with the present invention, there is provided a semiconductor manufacturing method that includes defining a substrate, depositing a first layer over the substrate, providing a layer of photoresist over the first layer, patterning and defining the photoresist layer to form at least one photoresist structure having at least one substantially vertical sidewall and one substantially horizontal surface, wherein a surface of the at least one substantially vertical sidewall is rough, and depositing a layer of polymer over the patterned and defined photoresist layer, wherein the polymer layer is substantially conformal and covers the at least one substantially vertical sidewall and one substantially horizontal surface, and wherein the polymer layer covers the rough surface of the at least one substantially vertical sidewall to form a substantially smooth profile.

Further in accordance with the present invention, there is provided a semiconductor manufacturing method that includes defining a semiconductor substrate, depositing a layer of first material over the semiconductor substrate, providing a layer of photoresist over the layer of first material, patterning and defining the photoresist layer to form at least one substantially vertical sidewall having a surface and one substantially horizontal sidewall, wherein the surface of the at least one substantially vertical sidewall includes a plurality of concave and a plurality of convex portions, and modifying the surface of the at least one substantially vertical sidewall with a layer of polymer for a predetermined deposition and etching ratio to form a substantially smooth profile, wherein the polymer layer is substantially conformal.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIGS. 1 and 2 are a cross-sectional views of the semiconductor manufacturing process steps of the present invention.

### DESCRIPTION OF THE EMBODIMENTS

Reference will now be made in detail to the exemplary embodiments of the invention, examples of which are illustrated in the accompanying drawings. Wherever possible, the same reference numbers will be used throughout the drawings to refer to the same or like parts.

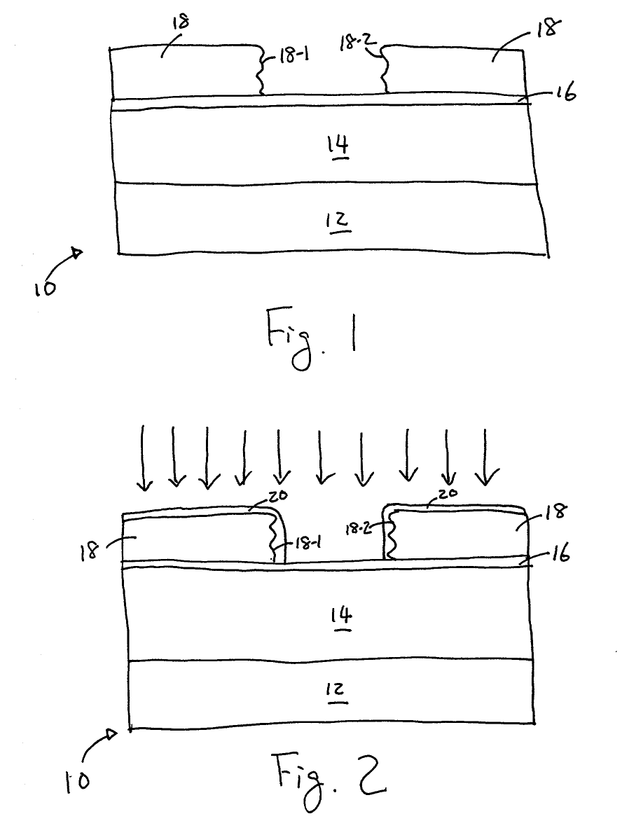

FIGS. 1-2 are cross-sectional views of the semiconductor manufacturing process steps of the present invention. Referring to FIG. 1, a semiconductor structure 10 is formed by first defining a wafer substrate 12. The wafer substrate 12 may be of any known semiconductor substrate material, such as silicon. A first layer 14 is then provided over the wafer substrate 12. In one embodiment, the first layer 14 is a semiconductor material, such as polysilicon. The first layer 14 may also be a dielectric layer or a metal layer. The first layer 14 may be deposited over the wafer substrate 12 by any known deposition process. In another embodiment, the first layer 14 is a dielectric material, in which case the first layer 14 may be deposited or grown over the wafer substrate 12.

An anti-reflection coating (ARC) layer 16 may optionally be provided over the first layer 14 to decrease the reflection from the first layer 14 in the subsequent manufacturing steps. A photoresist layer 18 is then provided over the ARC layer 16. In an embodiment in which an ARC layer is not provided, the photoresist layer 18 is deposited over the first layer 14.

After the photoresist layer 18 has been provided, it is patterned and defined using any known photolithographic process to form a patterned and defined photoresist layer 18. The patterned and defined photoresist layer 18 includes substantially vertical sidewalls 18-1 and 18-2. As shown in FIG. 1, the surfaces of the sidewalls 18-1 and 18-2 are rough in the shape of “standing waves,” having a plurality of concave and convex portions.

Referring to FIG. 2, a second layer 20 may be deposited over the patterned and defined photoresist layer 18 by any known chemical vapor deposition process. A known chemical vapor deposition process includes plasma enhanced chemical vapor deposition (PECVD) and low pressure chemical vapor deposition (LPCVD). The second layer 20 comprises a polymer, and is substantially conformal, such that the second layer 20 covers both the horizontal surfaces (not numbered) and vertical sidewalls 18-1 and 18-2 of the photoresist 18. The deposition process, especially the chemical vapor deposition processes that simultaneously provide both deposition and etching functionalities, may be adjusted such that the second layer 20 covers the entire vertical sidewalls 18-1 and 18-2 of the photoresist 18, or covers only the concave portions of the vertical sidewalls 18-1 and 18-2 of the photoresist 18 wherein the second layer 20 deposited on the convex portions is etched. The material characteristics of the second layer 20 enables the rough surfaces of the vertical sidewalls 18-1 and 18-2 to be covered with the second layer 20, presenting a substantially smooth and uniform vertical profile of the photoresist 18.

In one embodiment, the step of depositing the second layer 20 is performed with the PECVD process. The pressure used for forming the second layer 18 is in the range of approximately 7 mTorr to 30 mTorr. The upper source power ranges from approximately 600 wafts to 1300 watts, and the lower source power ranges from approximately 150 watts to 700 watts. The gas used may include one of difluoromethane (CH₂F₂), a mixture of difluoromethane and octafluorobutene (C₄F₈), and a mixture of difluoromethane and trifluoromethane (CHF₃). Moreover, argon (Ar), nitrogen (N₂), and carbon monoxide (CO) may be mixed with the gases introduced during the PECVD process. The carbon monoxide functions to capture fluorine radicals and fluoride ions generated by the fluoro-substituted hydrocarbons.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor manufacturing method, comprising:
defining a semiconductor substrate;
depositing a layer of first material over the semiconductor substrate;
providing a layer of photoresist over the layer of first material;
patterning and defining the photoresist layer to form at least one substantially vertical sidewall having a surface and one substantially horizontal sidewall; and
depositing a layer of polymer over the patterned and defined photoresist layer, wherein the polymer layer is substantially conformal and covers the at least one substantially vertical sidewall of the photoresist layer to form a substantially smooth profile.

2. The method as claimed in claim 1, wherein the deposition of the polymer layer is performed at a predetermined condition to form a substantially smooth profile.

3. The method as claimed in claim 1, wherein the deposition of the polymer layer covers the at least one substantially horizontal sidewall.

4. The method as claimed in claim 1, wherein the layer of polymer is deposited with plasma enhanced chemical vapor deposition at a pressure of between approximately 7 mTorr and 30 mTorr.

5. The method as claimed in claim 1, wherein the layer of first material comprises one of polysilicon, dielectric material or metallic material.

6. The method as claimed in claim 1, wherein the surface of the one substantially vertical sidewall is rough.

7. The method as claimed in claim 1 further comprising a step of depositing an anti-reflection coating over the layer of semiconductor material.

8. A semiconductor manufacturing method, comprising:
defining a substrate;
depositing a first layer over the substrate;
providing a layer of photoresist over the first layer;
patterning and defining the photoresist layer to form at least one photoresist structure having at least one substantially vertical sidewall and one substantially horizontal surface, wherein a surface of the at least one substantially vertical sidewall is rough; and
depositing a layer of polymer over the patterned and defined photoresist layer, wherein the polymer layer is substantially conformal and covers the at least one substantially vertical sidewall and one substantially horizontal surface, and wherein the polymer layer covers the rough surface of the at least one substantially vertical sidewall to form a substantially smooth profile.

9. The method as claimed in claim 8, wherein the first layer comprises polysilicon.

10. The method as claimed in claim 8 further comprising a step of depositing an anti-reflection coating over the first layer.

11. The method as claimed in claim 8, wherein the first layer is a dielectric layer.

12. The method as claimed in claim 8, wherein the first layer is a metallic layer.

13. A semiconductor manufacturing method, comprising:
defining a semiconductor substrate;
depositing a layer of first material over the semiconductor substrate;
providing a layer of photoresist over the layer of first material;
patterning and defining the photoresist layer to form at least one substantially vertical sidewall having a surface and one substantially horizontal sidewall, wherein the surface of the at least one substantially vertical sidewall includes a plurality of concave and a plurality of convex portions; and
modifying the surface of the at least one substantially vertical sidewall with a layer of polymer for a predetermined deposition and etching ratio to form a substantially smooth profile, wherein the polymer layer is substantially conformal.

14. The method as claimed in claim 13, wherein the layer of polymer covers the entire surface of the substantially vertical sidewall of the photoresist.

15. The method as claimed in claim 13, wherein the layer of polymer covers only the plurality of concave portions of the surface of the at least one substantially vertical sidewall.
